(19) United States
(12) Patent Application Publication
(10) Pub. No.: US 2013/0174890 A1
(43) Pub. Date: Jul. 11, 2013

(54) LIGHT COLLECTING SOLAR CELL MODULE

(71) Applicant: Ki Sung Park, Seongnam-si (KR)

(72) Inventor: Ki Sung Park, Seongnam-si (KR)

(73) Assignees: LEEONSMART Co., Ltd., Seoul (KR); Ki Sung Park, Gyeonggi-do (KR)

(21) Appl. No.: 13/575,375

(22) PCT Filed: Jan. 25, 2011
(86) PCT No.: PCT/KR11/00512

§ 371 Date: Sep. 26, 2012

(30) Foreign Application Priority Data
Jan. 26, 2010 (KR) 10-2010-0007116

(51) Int. Cl. H01L 31/052

(52) U.S. Cl. CPC H01L 31/0525
USPC 136/246

(57) ABSTRACT

A solar cell module allows sunlight collected in a vertical direction to be propagated to a solar cell by horizontal reflection, thereby shortening a focal length of travel of the sunlight and reducing a thickness thereof. In the solar cell module which collects sunlight and converts solar energy to electrical energy, the sunlight is collected in a parallel fashion in preset sections, and then the sunlight is propagated to the solar cell by being reflected at least once in each section. This configuration makes it possible for the overall size and weight of the solar cell module to be reduced because the focal length along which received sunlight is collected is reduced by reducing a width of the light-collecting module collecting the sunlight. Since the light-collecting module is divided into preset sections, the sunlight is received via a plurality of convex and concave lenses and parabolic reflectors in each section.

### TECHNICAL FIELD

The present invention relates, in general, to a solar cell module and, more particularly, to a solar cell module that reflects collected sunlight and propagates the reflected sunlight to a solar cell, thereby shortening a focal length along which the sunlight passes and reducing a thickness of the solar cell module.

### BACKGROUND ART

Due to the abrupt increase in the consumption of energy produced from coal, petroleum, nuclear fuel, liquefied natural gas, etc. as well as the exhaustion of energy sources such as coal, petroleum, nuclear fuel, liquefied natural gas, etc. that are being abruptly consumed, active research is currently being conducted into alternative energy that can substitute for such energy sources. This alternative energy includes wind power, tidal power, wave power, geothermal energy, hydrogen, solar heat, and so on. Among these, the alternative energy using sunlight is receiving much attention, and thus various types of research are being conducted into this alternative energy.

A light collecting solar cell module that uses the energy of sunlight as the alternative energy is the next generation of sunlight power generation modules that collect sunlight at a high magnification of several hundred times using an optical system such as a lens or a reflective mirror, and cause the sunlight to strike a solar cell that is made of a high-efficiency III-V compound semiconductor and has a small area, thereby generating electricity. Advantages if such a light collecting solar cell module are that it can realize high power generation efficiency and a low manufacturing cost compared to a flat plate solar cell module that uses existing silicon-based solar cells.

This light collecting solar cell module is generally divided into a refractive solar cell module that collects sunlight using Fresnel lenses and a reflective solar cell module that collects sunlight using parabolic reflectors.

Hereinafter, a structure of the sunlight module according to the related art will be discussed in greater detail with reference to FIG. 1. FIG. 1 schematically shows a light collecting solar cell module according to the related art.

As shown in FIG. 1, the light collecting solar cell module 10 according to the related art is configured so that a Fresnel lens 12 setting a cross-sectional length of a light collecting module 12 to A1 and a focal length to f1 is provided on an upper surface of a housing 11, and so that, when input in parallel through the light collecting module 12, sunlight is collected on a single focal point and then is propagated to a solar cell 14 having a III-V compound semiconductor component, and the energy of the collected sunlight is converted into electrical energy. This solar cell 14 is attached onto a hybrid integrated circuit (IC) board 15 having a bypass diode and a connector together. Here, the heat generated from the solar cell 14 is effectively dissipated using a heat sink 16 attached to a lower surface of the housing 11, thereby preventing the temperature of the solar cell 14 from increasing.

This light collecting solar cell module uses a compound semiconductor cell having a small area between 500:1 and 1000:1 as a solar cell. As such, the area of the solar cell itself, which accounts for a large part of the manufacturing cost of the solar cell, is reduced so that the manufacturing cost can be reduced when the solar cell module is manufactured.

Further, the light collecting solar cell module is configured so that the temperature coefficient of the output power is only 0.06%/° C., and thus can be installed in desert areas where the temperature is high.

However, in spite of the advantages of the light collecting solar cell module according to the related art, since the light collecting solar cell module uses a light collecting optical system, only the sunlight that is incident on the light-collecting optical system in a vertical direction is brought into focus oh the solar cell, and is and absorbed into the solar cell. Thus, the light collecting solar cell module is exposed to the problem of having to be installed on an upper portion of a follow-up device that follows the motion of the sun.

Further, the sunlight scattered due to external weather conditions, for instance, moisture, dust, etc. contained in cloud, fog, or air fail to be brought into focus on the solar cell, and thus the scattered sunlight is not absorbed into the solar cell.

In addition, the solar cell module uses the light collecting optical system to collect the sunlight, so that the thickness thereof is increased. This problem is as follows. Both the refractive solar cell module using the Fresnel lens and the reflective solar cell module using the parabolic reflector should increase the focal length along which the sunlight passes in order to have a high light collecting magnification of the sunlight and to prevent the loss of light generated from the light collecting optical system even though the light collecting magnification is high. For this reason, the overall thickness of the light collecting solar cell module is increased.

Hereinafter, the light transmittance according to the focal length of the light collecting solar cell module according to the related art will be discussed in greater detail with reference to FIG. 2. FIG. 2 is a graph showing the light transmittance according to the focal length of the solar cell module of FIG. 1.

As shown in FIG. 2, it will be noticed from the curve of the light collecting solar cell module that the f number of sunlight is 1 or more so as to obtain a light transmittance of 80% or more. Here, the f number refers to a value obtained by dividing the focal length of the sunlight collected through a light-collecting module by the diameter of the light collecting module.

For example, in the case of a solar cell module in which a solar cell has a size of 1 cm×1 cm and a light collecting magnification of 1000 times, the focal length should be 45 cm or more. As a result, there occurs the problem of the overall size and weight of the solar cell module being increased.

### DISCLOSURE

### Technical Problem

Accordingly, the present invention has been made keeping in mind the above problems occurring in the related art, and an object of the present invention is to provide a solar cell module, which reflects collected sunlight one or more times and propagates the reflected sunlight to a solar cell, thereby shortening the focal length traveled by the sunlight to reduce the thickness and size thereof.

Further, the present invention serves to provide a solar cell module, which shortens the focal length for sunlight to reduce thickness and size thereof, thereby reducing the manufacturing cost.

### Technical Solution

According to an aspect of the present invention, there is provided a solar cell module which collects sunlight and converts solar energy to electrical energy. The solar cell module includes: a plurality of light-collecting modules partitioned in a horizontal direction to collect the sunlight; at least one solar cell generating electrical energy by collecting the sunlight; and a plurality of reflecting modules reflecting the sunlight collected by a plurality of light-collecting regions one or more times and propagating the reflected sunlight to the solar cell.

Here, the light-collecting modules may be disposed in a shape of concentric circles.

According to another aspect of the present invention, there is provided a solar cell module which collects sunlight and converts solar energy to electrical energy. The solar cell module includes: a plurality of light-collecting modules partitioned in a horizontal direction to collect the sunlight; at least one solar cell generating electrical energy by collecting the sunlight; a plurality of reflecting modules reflecting the sunlight collected by a plurality of light-collecting regions one or more times and propagating the reflected sunlight to the solar cell; and a prism module disposed on the solar cell.

Here, the light-collecting modules may include a plurality of convex lens, and be reduced in thickness as a diameter of each convex lens becomes shorter.

Further, each reflecting module may further include a parabolic reflector disposed on a lower surface thereof so that the sunlight is collected on the solar cell.

Also, the prism module may have a shape of an inverse trapezoidal prism, and an area of a lower rectangle of the inverse trapezoidal prism may be equal to an area of the solar cell.

According to another aspect of the present invention, there is provided a solar cell module which collects sunlight and converts solar energy to electrical energy. The solar cell module includes: a light-collecting module including a plurality of convex lenses partitioned in a horizontal direction to collect the sunlight; at least one solar cell generating electrical energy after collecting the sunlight; a plurality of reflecting modules configured to reflect the sunlight collected by a plurality of light-collecting regions one or more times and to propagate the reflected sunlight to the solar cell; and a prism module disposed on the solar cell. Each reflecting module further includes a parabolic reflector disposed on a lower surface thereof so as to be inclined at a preset angle of inclination so that the sunlight is propagated to the solar cell.

Here, the inclined angle may be obtained using an equation expressed by:

θ=tan⁻¹(d/al)

where d is a thickness of the parabolic reflector, and al is a diameter of the convex lens.

According to another aspect of the present invention, there is provided a solar cell module which collects sunlight and converts solar energy to electrical energy. The solar cell module includes: a light-collecting module including a plurality of convex lenses partitioned in a horizontal direction to collect the sunlight; at least one solar cell generating electrical energy by collecting the sunlight; a plurality of reflecting modules including parabolic reflectors allowing the sunlight to be propagated to the solar cell, and configured to reflect the sunlight collected by a plurality of light-collecting regions one or more times and to propagate the reflected sunlight to the solar cell; and a prism module disposed on the solar cell. Each parabolic reflector is configured so that upper and lower portions thereof are inversely disposed so that one surface thereof has a convex shape, and propagates the reflected sunlight in parallel.

Here, each convex lens collecting the sunlight may have a focal point formed at a position lower than a position at which the corresponding parabolic reflector is disposed.

According to another aspect of the present invention, there is provided a solar cell module which collects sunlight and converts solar energy to electrical energy. The solar cell module includes: a plurality of light-collecting modules partitioned in a horizontal direction to collect the sunlight; at least one solar cell generating electrical energy by collecting the sunlight; a plurality of reflecting modules including planar reflectors allowing the sunlight to be propagated to the solar cell, and configured to reflect the sunlight collected by a plurality of light-collecting regions one or more times and to propagate the reflected sunlight to the solar cell; and a prism module disposed on the solar cell. The light-collecting modules are configured so that a plurality of convex lenses are disposed on an upper surface thereof in respective sections, and so that a plurality of concave lenses are disposed so as to correspond to the convex lenses so as to cause the sunlight collected through the convex lenses to be propagated to the solar cell.

According to another aspect of the present invention, there is provided a solar cell module which collects sunlight and converts solar energy to electrical energy. The solar cell module includes: a plurality of light-collecting modules partitioned in a horizontal direction to collect the sunlight; at least one solar cell generating electrical energy after collecting the sunlight; a plurality of reflecting modules including planar reflectors allowing the sunlight to be propagated to the solar cell, and configured to reflect the sunlight collected by a plurality of light-collecting regions one or more times and to propagate the reflected sunlight to the solar cell; and a prism module disposed on the solar cell. The light-collecting modules are configured so that a plurality of convex lenses are disposed on an upper surface thereof in respective sections, so that a plurality of concave lenses are disposed on a lower surface thereof so as to correspond to the convex lenses, and so that the convex and concave lenses are mutually disposed in one body.

According to another aspect of the present invention, there is provided a solar cell module which collects sunlight and converts solar energy to electrical energy. The solar cell module includes: a plurality of light-collecting modules partitioned in a horizontal direction to collect the sunlight; at least one solar cell generating electrical energy after collecting the sunlight; a plurality of reflecting modules including planar reflectors allowing the sunlight to be propagated to the solar cell, and configured to reflect the sunlight collected by a plurality of light-collecting regions one or more times and to propagate the reflected sunlight to the solar cell; and a prism module disposed on the solar cell. The light-collecting modules are configured so that a plurality of parabolic reflectors are disposed on an upper surface thereof, and so that a plurality of concave lenses are disposed so as to correspond to the parabolic reflectors so as to cause the sunlight collected through the parabolic reflectors to be propagated to the solar cell.

Particularly, each light-collecting module and each reflecting module may be formed of at least one of glass and poly methyl methacrylate (PMMA).

### Advantageous Effects

In the light collecting solar cell module of the present invention, the light-collecting module to which the sunlight is input is divided into preset sections, and the sunlight is received through the plurality of convex arid concave lenses and parabolic reflectors disposed in the respective sections, and thus a width of each convex lens of the light-collecting module is reduced, and a focal position at which the input sunlight is collected is lowered in proportion to the reduced width. As such, the size and weight of the solar cell module can be reduced.

Further, in the light collecting solar cell module of the present invention, the sunlight input to the light-collecting module is reflected one or more times, thereby reducing the focal length within which the sunlight is collected. Thus, the overall size of the solar cell module is reduced, and thus the solar cell module is made lightweight.

Particularly, in the light collecting solar cell module of the present invention, the light-collecting module and the reflecting module can be manufactured by molding. Thus, in the event of mass production, assembly automation is made easy, so that the manufacturing cost can be reduced.

Furthermore, in the light collecting solar cell module of the present invention, the light-collecting module to which the sunlight is input is divided into preset sections, and the sunlight is received in the sections. The received sunlight is propagated to the solar cell in such a way that the loss of propagation minimized, so that the efficiency of the solar cell module can be increased.

In addition, in the light collecting solar cell module of the present invention, the sunlight received through the convex and concave lenses and the parabolic reflectors provided to the light-collecting module can be easily propagated to the solar cell via a waveguide and the prism module.

### DESCRIPTION OF DRAWINGS

FIG. 1 schematically shows a light collecting solar cell module according to the related art.

FIG. 2 is a graph showing the light transmittance according to a focal length in the solar cell module of FIG. 1.

FIG. 3 is a cross-sectional view showing a light collecting solar cell module according to an exemplary embodiment of the present invention.

FIG. 4 is an enlarged cross-sectional view showing a part of the light collecting solar cell module of FIG. 3.

FIG. 5 is a cross-sectional view showing a light collecting solar cell module according to another exemplary embodiment of the present invention.

FIG. 6 is an enlarged cross-sectional view showing a part of the light collecting solar cell module of FIG. 5.

FIG. 7 is a cross-sectional view showing a light collecting solar cell module according to another exemplary embodiment of the present invention.

FIG. 8 is an enlarged cross-sectional view showing a part of the light collecting solar cell module of FIG. 7.

FIG. 9 is a cross-sectional view showing a light collecting solar cell module according to another exemplary embodiment of the present invention.

FIG. 10 is an enlarged cross-sectional view showing a part of the light collecting solar cell module of FIG. 9.

FIG. 11 is a cross-sectional view showing a light collecting solar cell module according to another exemplary embodiment of the present invention.

FIG. 12 is a cross-sectional view showing a light collecting solar cell module according to another exemplary embodiment of the present invention.

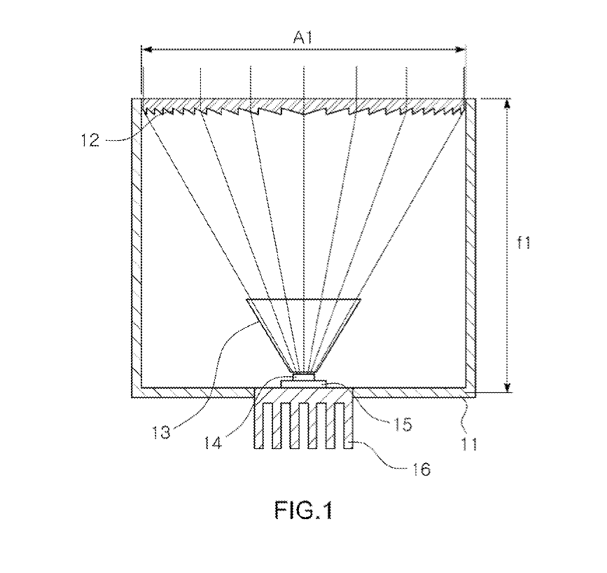

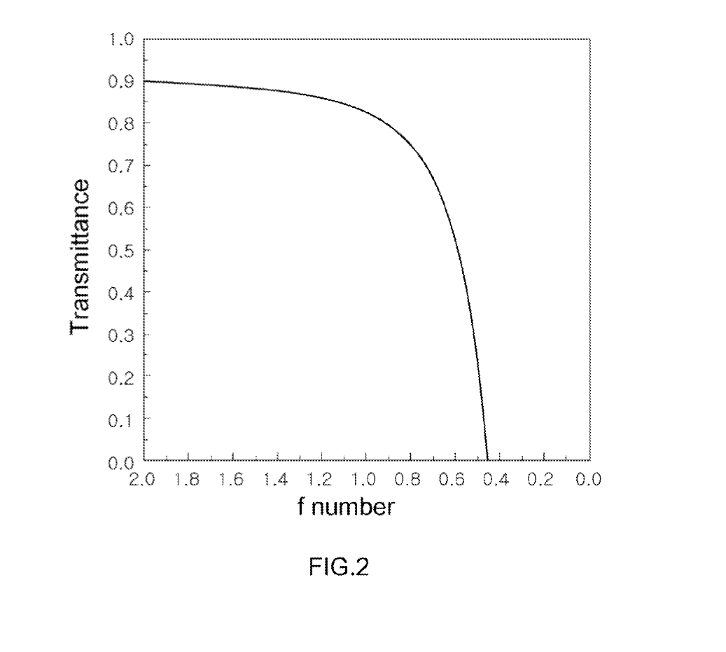

### MODE FOR INVENTION

Hereinbelow, exemplary embodiments of the present invention will be described in detail with reference to the accompanying drawings so as to be easily carried out by a person having ordinary skill in the art. However, it should be understood that the embodiments of the present invention may be changed to a variety of other embodiments and the scope and spirit of the present invention are not limited to the embodiments described hereinbelow.

Hereinafter, a light collecting solar cell module according to an exemplary embodiment of the present invention will be discussed with reference to FIG. 3. FIG. 3 is a schematic cross-sectional view showing a light collecting solar cell module according to an exemplary embodiment of the present invention.

As shown in FIG. 3, the light collecting solar cell module 100 of the present invention includes a light-collecting module 120 that collects sunlight in a parallel fashion in preset sections, at least one solar cell 160 that generates electrical energy by collecting the sunlight, a reflecting module 130 that reflects the collected sunlight one or more times, a prism module 140 that propagates the sunlight reflected one or more times to the solar cell 160, and a housing 110 that supports these components.

The light-collecting module 120 is disposed on an upper surface of the housing 110 so as to collect the sunlight in the preset sections. This light-collecting module 120 is configured to divide the upper surface of the housing 110 into sections in a concentric circle shape, and to dispose convex lenses 122 in the sections. Here, a focal point P1 at which the sunlight is collected varies depending on the diameter of each convex lens 122. As a result, as the diameter of each convex lens 122 becomes shorter, the thickness of each convex lens becomes smaller. Accordingly, the overall size of the solar cell module 100 is reduced.

The solar cell 160 receives the collected sunlight from the light-collecting module 120, converts sunlight energy into electrical energy, and generates the electrical energy.

The reflecting module 130 is disposed on a lower surface of the housing 110 so as to face the light-collecting module 120, and particularly has parabolic reflectors 132 disposed on a lower surface thereof in order to propagate the collected sunlight to the solar cell 160 disposed in the center of the housing 110. Thus, when the sunlight collected by the light-collecting module 120 reaches the parabolic reflectors 132 disposed on the lower surface of the reflecting module 130, the sunlight is reflected by the parabolic reflectors 132, so that a travelling direction of the sunlight is changed from a vertical state to a horizontal state.

Particularly, the light-collecting module 120 and the reflecting module 130 may be formed of at least one of poly methyl methacrylate (PMMA) and glass.

The prism module 140 is disposed at a lower portion of the reflecting module 130 so as to be parallel to the solar cell 160 disposed on a lowermost surface of the housing 110. This prism module 140 has the shape of an inverse trapezoidal prism. Here, the area of a lower rectangle of the inverse trapezoidal prism is equal to a surface area of the solar cell 160.

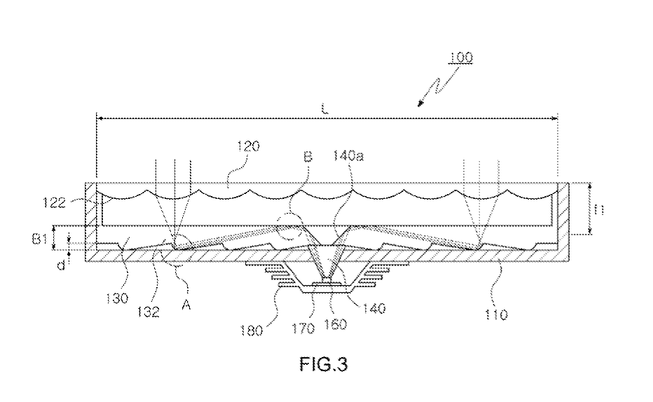

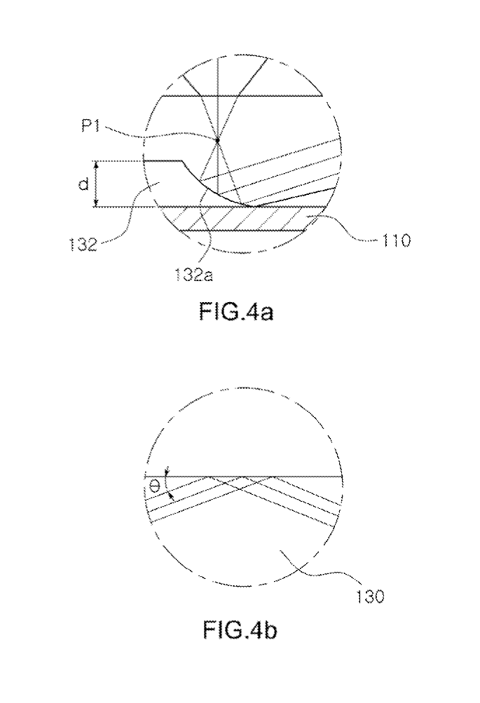

Thus, in the light collecting solar cell module 100 of the present invention, first, the sunlight is collected through the convex lenses 122 disposed in the sections, and the sunlight collected by each convex lens 122 is collected at a first focal point P1. Hereinafter, a process of reflecting the sunlight collected by the light collecting solar cell module of FIG. 3 will be discussed in greater detail. FIG. 4 is an enlarged cross-sectional view showing a part of the light collecting solar cell module of FIG. 3.

As shown in FIG. 4a, the sunlight collected by the light-collecting module 120 is propagated to the reflecting module 130, and thus is brought to the first focal point P1. The sunlight brought to the first focal point P1 reaches each parabolic reflector 132 disposed on the lower surface of the reflecting module 130, and the sunlight that reaches each parabolic reflector 132 is then reflected off of each parabolic reflector 132. Thereby, the traveling direction of the sunlight changes from a vertical direction to a horizontal direction.

In this manner, part of the sunlight reflected by each parabolic reflector 132 is propagated to an upper surface of the reflecting module 130 depending on the position at which the sunlight is reflected from each parabolic reflector 132, as shown in FIG. 4b. However, the sunlight, which is reflected from each parabolic reflector 132 and is propagated to the upper surface of the reflecting module 130, is subjected to total reflection. As such, the totally reflected sunlight is again propagated to the prism module 140 disposed at a lower central portion of the reflecting module 130.

Referring to FIG. 3 again, as described above, the sunlight collected in the sections is subject to a change in the traveling direction by the reflecting module 130 and the parabolic reflectors 132, and is input the solar cell 160 disposed under the prism module 140 via the prism module 140 disposed at a lower central portion of the housing 110.

Thus, the energy of the sunlight collected on the solar cell 160 is converted into electrical energy. The electrical energy is propagated to the outside by a hybrid integrated circuit (IC) board 170 that connects an anode and cathode formed on the solar cell 160. Here, the hybrid IC board 170 may be formed of alumina. Particularly, a heat sink 180 is disposed under the hybrid IC board 170 so as to surround the prism module 140, the solar cell 160, and the hybrid IC board 170, so that these key parts are protected from heat and the external environment.

Hereinafter, a light collecting solar cell module according to another embodiment of the present invention will be discussed in detail with reference to FIG. 5. FIG. 5 is a cross-sectional view showing a light collecting solar cell module according to another embodiment of the present invention. Here, the light collecting solar cell module 200 according to another embodiment of the present invention will not be described regarding the same portions as the light collecting solar cell module 100 described with reference to FIG. 4, but will be described regarding differences from the light collecting solar cell module 100.

As shown in FIG. 5, the light collecting solar cell module 200 according to another embodiment of the present invention includes a light-collecting module 220 disposed on an upper surface of a housing 210, at least one solar cell 260 generating electrical energy by collecting sunlight, a reflecting module 230 disposed on a lower surface of the housing 210, a prism module 240 disposed at a lower portion of the reflecting module 130 so as to be parallel to the solar cell 260 disposed on a lowermost surface of the housing 210, and the housing 210 supporting these components.

Among the components of the light collecting solar cell module 200 according to the other embodiment of the present invention, the remaining components excluding the reflecting module 230 are the same as those described with reference to FIG. 3 (→4), and so description thereof will be omitted.

The reflecting module 230 includes parabolic reflectors 232 that are disposed at an inclined angle on a lower surface thereof so that the sunlight is collected onto the solar cell 260. The parabolic reflectors 232 are inclined upwards at an inclined angle and are disposed in a toothed shape, compared to the parabolic reflectors 132 shown in FIG. 4. Here, the inclined angle of the parabolic reflectors 232 may be calculated using the following equation that has as arguments the thickness of each parabolic reflector 232 and the diameter of each convex lens 222.

θ=tan⁻¹(d/al) Equation 1

where d is the thickness of the parabolic reflector, and al is the diameter of the convex lens. This shows that the inclined angle θ of the parabolic reflector is proportional to the thickness d of the parabolic reflector, and is inversely proportional to the diameter al of the convex lens.

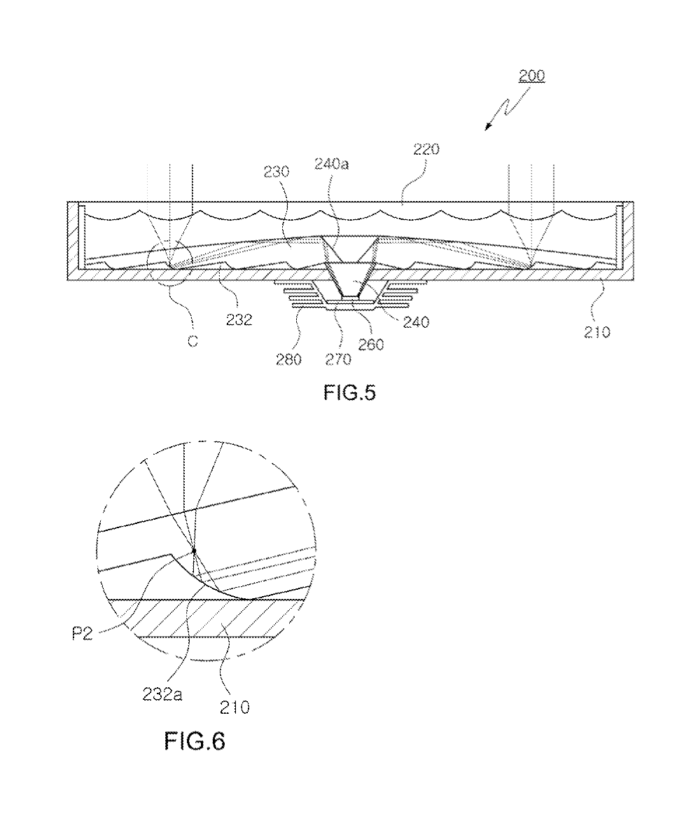

Hereinafter, the sunlight reflected by the parabolic reflectors disposed so as to be inclined at an angle will be discussed in greater detail with reference to FIG. 6. FIG. 6 is an enlarged cross-sectional view showing a part c of the light collecting solar cell module of FIG. 5.

As shown in FIG. 6, the sunlight collected by the light-collecting module 220 is propagated to the reflecting module 230, and thus is brought to a second focal point P2. The sunlight brought to the second focal point P2 reaches each parabolic reflector 232 disposed at the lower portion of the reflecting module 230, and the sunlight that reaches each parabolic reflector 232 is reflected off of each parabolic reflector 232. Thereby, the traveling direction of the sunlight is changed from a vertical direction to a horizontal direction. Here, the reflection of the sunlight caused by each parabolic reflector 232 may be subjected to internal total reflection created by the difference between the refractive index of the reflecting module 230 and the refractive index of the external air, and may undergo total reflection because of a metal coating layer formed on the lower surface of the reflecting module 230.

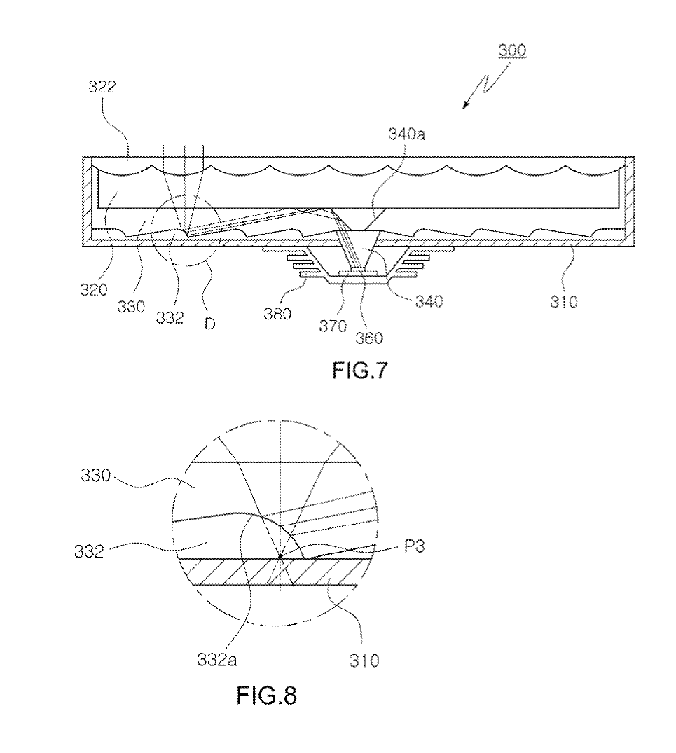

Hereinafter, a light collecting solar cell module according to another embodiment of the present invention will be discussed in detail with reference to FIG. 7. FIG. 7 is a cross-sectional view showing a light collecting solar cell module according to another embodiment of the present invention.

As shown in FIG. 7, the light collecting solar cell module 300 according to another embodiment of the present invention includes a light-collecting module 320 disposed on an upper surface of a housing 310, at least one solar cell 360 generating electrical energy by collecting sunlight, a reflecting module 330 disposed on a lower surface of the housing 310, a prism module 340 disposed at a lower portion of the reflecting module 330 so as to be parallel to the solar cell 360 disposed on a lowermost surface of the housing 310, and the housing 310 supporting these components.

The reflecting module 330 of the light collecting solar cell module 300 according to another embodiment of the present invention is configured so that upper and lower portions of each parabolic reflector 332 are disposed on the lower surface of the reflecting module 330 in an inverse shape so that one surface of each parabolic reflector 332 has a convex shape in order to collect the sunlight onto the center of the reflecting module 230.

Hereinafter, the sunlight reflected by each parabolic reflector 332 whose upper and lower portions are inversely disposed will be discussed in greater detail with reference to FIG. 8. FIG. 8 is an enlarged cross-sectional view showing a part D of the light collecting solar cell module 300 of FIG. 7.

As shown in FIG. 8, the sunlight collected through convex lenses 322 of the light-collecting module 320 is propagated to the reflecting module 330. Thus, before the sunlight is collected at a third focal point P3, the traveling direction of the sunlight is changed from a vertical direction to a horizontal direction by each parabolic reflector 332 whose upper and lower portions are disposed in an inverse shape.

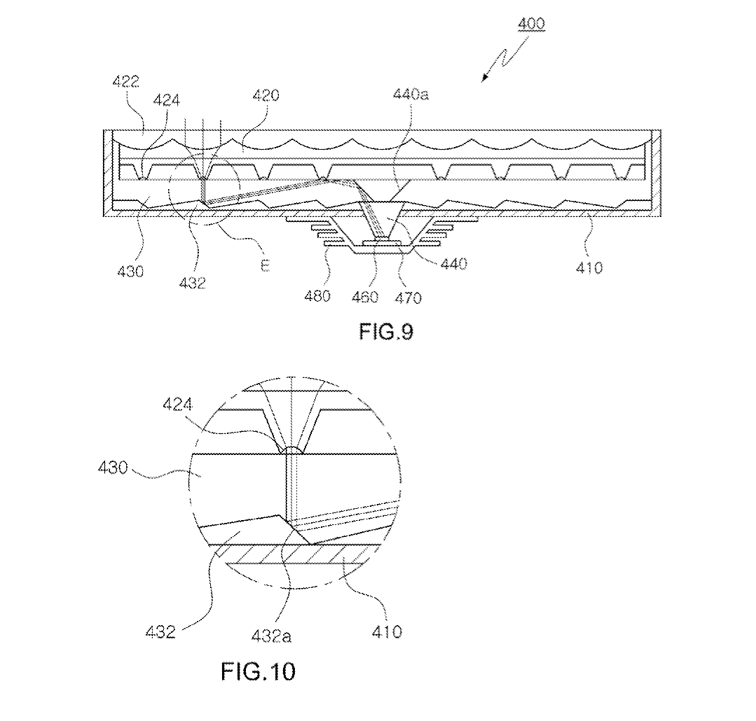

In this manner, the sunlight whose traveling direction is changed to the horizontal direction is propagated to the center of the reflecting module 330. Hereinafter, a light collecting solar cell module according to another embodiment of the present invention will be discussed in detail with reference to FIG. 9. FIG. 9 is a cross-sectional view showing a light collecting solar cell module according to another embodiment of the present invention.

As shown in FIG. 9, a light-collecting module 420 of the light collecting solar cell module 400 according to another embodiment of the present invention is disposed on an upper surface of a housing 410 so as to collect sunlight in preset sections. This light-collecting module 420 is configured so that a plurality of convex lenses 422 are disposed on the upper surface of a housing 410 in the respective sections, and so that a plurality of concave lenses 424 are disposed on a lower surface of the light-collecting module 420 so as to correspond to the convex lenses 422.

A reflecting module 430 is configured so that planar reflectors are disposed on a lower surface thereof, and thus sunlight collected through the light-collecting module 420 is propagated to the center thereof.

Hereinafter, the light-collecting module and reflecting module of the present invention will be discussed in greater detail with reference to FIG. 10. FIG. 10 is an enlarged cross-sectional view showing a part E of the light collecting solar cell module of FIG. 9.

As shown in FIG. 10, in the light collecting solar cell module 400 according to another embodiment of the present invention, the sunlight is collected by the convex lenses 422 of the light-collecting module 420 which are disposed in the preset sections, and the sunlight transmitted through the convex lenses 422 is propagated to the concave lenses 424 disposed in parallel to the convex lenses 422 in a parallel fashion. In this manner, the parallel sunlight is propagated to the reflecting module 430, and reaches the planar reflectors 432 disposed on the lower surface of the reflecting module 430. Thus, the planar reflectors 432 change the traveling direction of the sunlight from a vertical direction to a horizontal direction.

In this manner, the light collecting solar cell module 400 according to another embodiment of the present invention is configured so that the convex and concave lenses are disposed at the upper and lower portions of the light-collecting module so as to correspond to each other, and thus is easy to manufacture.

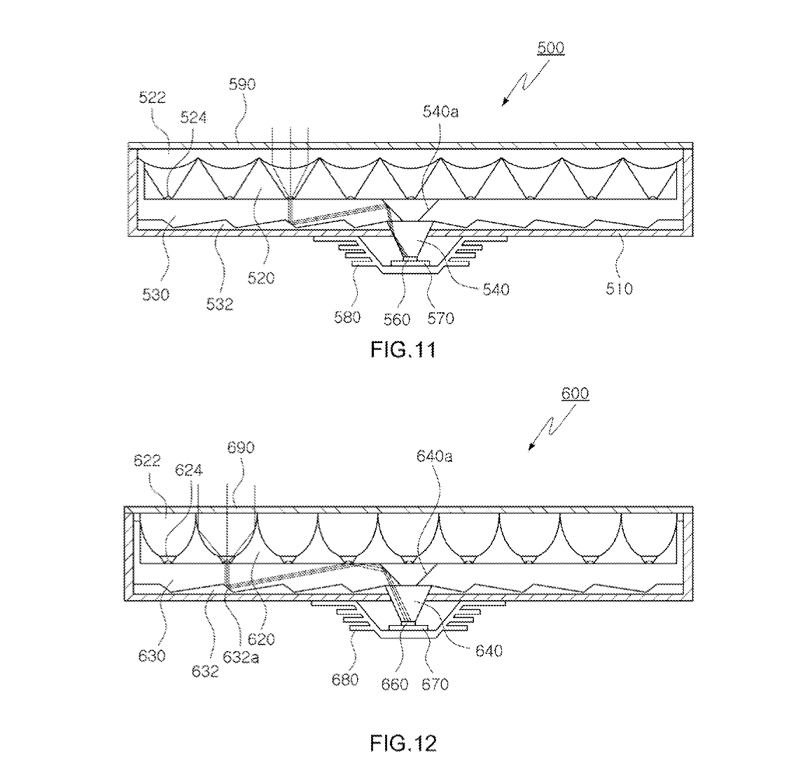

Hereinafter, a light collecting solar cell module according to another embodiment of the present invention will be discussed in detail with reference to FIG. 11. FIG. 11 is a cross-sectional view showing a light collecting solar cell module according to another embodiment of the present invention.

As shown in FIG. 11, a light-collecting module 520 of the light collecting solar cell module 500 according to another embodiment of the present invention is configured so that, in the light-collecting module of the light collecting solar cell module 400 described above with reference to FIG. 9, a plurality of convex and concave lenses 522 and 524 are disposed in the respective sections in an integrated form.

Further, the light collecting solar cell module 500 is configured so that a glass plate member 590 is disposed on an upper surface of the light-collecting module 520 so as to cover the entire light-collecting module 520 having the plurality of convex and concave lenses 522 and 524 disposed in the respective sections, so that it can protect the upper surface of each convex lens 522 from the outside and effectively transmit the collected sunlight at the same time.

Hereinafter, light collecting solar cell module according to another embodiment of the present invention will be discussed in detail with reference to FIG. 12. FIG. 12 is a cross-sectional view showing a light collecting solar cell module according to another embodiment of the present invention.

As shown in FIG. 12, a light-collecting module 620 of the light collecting solar cell module 600 according to another embodiment of the present invention is configured so that, in the light-collecting module of the light collecting solar cell module 500 described above with reference to FIG. 11, parabolic reflectors 622 are disposed in the respective sections. Here, a focal point at which sunlight is collected onto each parabolic reflector 622 is formed at a position below the apex of each parabolic reflector. The sunlight passes through each concave lens 624 which is disposed at a position above the focal point, and then is put in parallel again.

Further, the light collecting solar cell module 600 is configured so that a glass plate member 690 is disposed on an upper surface of the light-collecting module 620 having the plurality of parabolic reflectors and concave lenses 622 and 624, which are disposed in the respective sections. This glass plate member 690 is disposed on the upper surface of the light-collecting module 620, so that it can protect an upper surface of each parabolic reflector 622 from the outside and simultaneously transmit the collected sunlight.

In the light collecting solar cell module of the present invention, the light-collecting module to which the sunlight is input is divided into preset sections, and the sunlight is received through the plurality of convex and concave lenses and parabolic reflectors disposed in the respective sections, and thus a width of each convex lens of the light-collecting module is reduced, and the focal position at which the input sunlight is collected is lowered in proportion to the reduced width. For this reason, the size and weight of the solar cell module can be reduced.

Further, in the light collecting solar cell module of the present invention, the sunlight input to the light-collecting module is reflected one or more times, thereby reducing the focal length along which the sunlight is collected. Thus, the overall size of the solar cell module is reduced, and thus the solar cell module can be made lightweight.

Particularly, in the light collecting solar cell module of the present invention, the light-collecting module and the reflecting module can be manufactured by molding. Thus, in the event of mass production, assembly automation is made easy, so that the manufacturing cost can be reduced.

Furthermore, in the light collecting solar cell module of the present invention, the light-collecting module to which the sunlight is input is divided into preset sections, and the sunlight is received in the sections. The received sunlight is propagated to the solar cell with a minimal loss of propagation, so that the efficiency of the solar cell module can be increased.

In addition, in the light collecting solar cell module of the present invention, the sunlight received through the convex and concave lenses and the parabolic reflectors provided to the light-collecting module can be easily propagated to the solar cell via a waveguide and the prism module.

Although the embodiments of the present invention have been disclosed for illustrative purposes, those skilled in the art will appreciate that various modifications, additions and substitutions are possible, without departing from the scope and spirit of the invention as disclosed in the accompanying claims.

### INDUSTRIAL APPLICABILITY

According to the present invention, the light-collecting module to which the sunlight is input is divided into preset sections, and the sunlight is received through the plurality of convex and concave lenses arid parabolic reflectors disposed in the respective sections, and thus a width of each convex lens of the light-collecting module is reduced, and the focal position at which the input sunlight is collected is lowered in proportion to the reduced width. As such, the size and weight of the solar cell module can be reduced. Particularly, of relevance to the field of solar cells, the size and weight of the solar cell module are reduced, and thus the industrial applicability is high.

1. A solar cell module which collects sunlight and converts solar energy to electrical energy, the solar cell module comprising:
a plurality of light-collecting modules partitioned in a horizontal direction to collect the sunlight;
at least one solar cell generating electrical energy by collecting the sunlight; and
a plurality of reflecting modules reflecting the sunlight collected by a plurality of light-collecting regions one or more times and propagating the reflected sunlight to the solar cell.

2. The solar cell module according to claim 1, wherein the light-collecting modules are disposed in a shape of concentric circles.

3. The solar cell module according to claim 1,
further comprising a prism module disposed on the solar cell.

4. The solar cell module according to claim 3, wherein the light-collecting modules include a plurality of convex lenses and are reduced in thickness as a diameter of each convex lens becomes shorter.

5. The solar cell module according to claim 3, wherein each reflecting module further includes a parabolic reflector disposed on a lower surface thereof so that the sunlight is collected on the solar cell.

6. The solar cell module according to claim 3, wherein the prism module has a shape of an inverse trapezoidal prism, and an area of a lower rectangle of the inverse trapezoidal prism is equal to an area of the solar cell.

7. The solar cell module according to claim 1,
wherein each reflecting module further includes a parabolic reflector disposed on a lower surface thereof so as to be inclined at a preset angle of inclination so that the sunlight is propagated to the solar cell.

8. The solar cell module according to claim 7, wherein the inclined angle is obtained using an equation expressed by
θ=tan⁻¹(d/al)
where d is a thickness of the parabolic reflector, and al is a diameter of the convex lens.

9. A solar cell module which collects sunlight and converts solar energy to electrical energy, the solar cell module comprising:
a light-collecting module including a plurality of convex lenses partitioned in a horizontal direction to collect the sunlight;
at least one solar cell generating electrical energy by collecting the sunlight;
a plurality of reflecting modules including parabolic reflectors allowing the sunlight to be propagated to the solar cell, and configured to reflect the sunlight collected by a plurality of light-collecting regions one or more times and to propagate the reflected sunlight to the solar cell; and
a prism module disposed on the solar cell,
wherein each parabolic reflector is configured so that upper and lower portions thereof are inversely disposed so that one surface thereof has a convex shape, and propagates the reflected sunlight in parallel.

10. The solar cell module according to claim 9, wherein each convex lens collecting the sunlight has a focal point formed at a position lower than a position at which the corresponding parabolic reflector is disposed.

11. A solar cell module which collects sunlight and converts solar energy to electrical energy, the solar cell module comprising:
a plurality of light-collecting modules partitioned in a horizontal direction to collect the sunlight;
at least one solar cell generating electrical energy by collecting the sunlight;
a plurality of reflecting modules including planar reflectors allowing the sunlight to be propagated to the solar cell, and configured to reflect the sunlight collected by a plurality of light-collecting regions one or more times and to propagate the reflected sunlight to the solar cell; and
a prism module disposed on the solar cell.

12. The solar cell module according to claim 11,
wherein the light-collecting modules are configured so that a plurality of convex lenses are disposed on an upper surface thereof in respective sections, so that a plurality of concave lenses are disposed on a lower surface thereof so as to correspond to the convex lenses, and so that the convex and concave lenses are mutually disposed in one body.

13. The solar cell module according to claim 11,
wherein the light-collecting modules are configured so that a plurality of parabolic reflectors are disposed on an upper surface thereof, and so that a plurality of concave lenses are disposed so as to correspond to the parabolic reflectors so as to cause the sunlight collected through the parabolic reflectors to be propagated to the solar cell.

14. The solar cell module according to claim 1, wherein each light-collecting module and each reflecting module are formed of at least one of glass and poly methyl methacrylate (PMMA).

15. The solar cell module according to claim 11,
wherein the light-collecting modules are configured so that a plurality of convex lenses are disposed on an upper surface thereof in respective sections, and so that a plurality of concave lenses are disposed so as to correspond to the convex lenses so as to cause the sunlight collected through the convex lenses to be propagated to the solar cell.
